(19) United States
(12) Patent Application Publication
(10) Pub. No.: US 2026/0229851 A1
(43) Pub. Date: Aug. 6, 2026

(54) SEMICONDUCTOR OPTICAL AMPLIFIER

(71) Applicant: Innolume GmbH, Dortmund (DE)

(72) Inventors: Sergei Poltavtsev, Dortmund (DE); Alexey Gubenko, Dortmund (DE); Artem Petrenko, Dortmund (DE); Aleksei Borodkin, Dortmund (DE)

(21) Appl. No.: 19/046,797

(22) Filed: Feb. 6, 2025

(51) Int. Cl. H01S 5/343; H01S 5/10; H01S 5/34

(52) U.S. Cl. CPC H01S 5/34313; H01S 5/101; H01S 5/1014; H01S 5/341

(57) ABSTRACT

According to an embodiment, a semiconductor optical amplifier comprises: an optical input; an optical output; a waveguide optically coupled to the optical input and to the optical output, wherein the waveguide comprises at least two bent sections; and a plurality of semiconductor layers epitaxially deposited on a substrate, wherein the waveguide is positioned on top of the plurality of semiconductor layers and the plurality of semiconductor layers comprises an active region configured to amplify an optical signal propagating in the at least one waveguide.

### TECHNICAL FIELD

The present disclosure relates to the field of optics, and more particularly to a semiconductor optical amplifier and a method for forming at least one waveguide.

### BACKGROUND

Semiconductor optical amplifiers (SOAs) play an important role in various modern optical applications, such as in optical data transmission. Low noise, high power conversion efficiency, wide gain bandwidth, high small signal gain, and a small chip footprint are some of the desirable characteristics for a SOA.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

It is an object to provide a semiconductor optical amplifier and a method for forming at least one waveguide. The foregoing and other objects are achieved by the features of the independent claims. Further implementation forms are apparent from the dependent claims, the description and the figures.

According to a first aspect, a semiconductor optical amplifier comprises: an optical input; an optical output; a waveguide optically coupled to the optical input and to the optical output, wherein the waveguide comprises at least two bent sections; and a plurality of semiconductor layers epitaxially deposited on a substrate, wherein the waveguide is positioned on top of the plurality of semiconductor layers and the plurality of semiconductor layers comprises an active region configured to amplify an optical signal propagating in the waveguide, wherein the plurality of semiconductor layers further comprises a bottom cladding layer and a top cladding layer, wherein a refractive index of the active region is greater than a refractive index of the bottom cladding layer and a refractive index of the top cladding layer.

In an implementation form of the first aspect, the active region comprises at least of: quantum wells, quantum dots, quantum wires, or/and quantum dashes.

In another implementation form of the first aspect, the plurality of semiconductor layers is realized in a III-V semiconductor material composition.

In another implementation form of the first aspect, the plurality of semiconductor layers is realized in gallium arsenide and the active region comprises indium arsenide quantum dots.

In another implementation form of the first aspect, the active region comprises indium arsenide quantum dots embedded in indium gallium arsenide quantum wells.

In another implementation form of the first aspect, the waveguide comprises ridge waveguide on top of the plurality of semiconductor layers.

In another implementation form of the first aspect, a height of the ridge waveguide is in the range of 1 to 3 micrometers (μm).

In another implementation form of the first aspect, a bend radius of the at least two bent sections is in the range of 7 to 16 millimeters (mm).

In another implementation form of the first aspect, the waveguide comprises at least a first bent section and a second bent section, wherein the first bent section is located on a first side of a straight line from the optical input to the optical output and the second bent section is located on a second side of the straight line from the optical input to the optical output.

In another implementation form of the first aspect, the first bent section has a first bend radius and the second bent section has a second bend radius, different from the first bend radius.

In another implementation form of the first aspect, the optical input is arranged onto an input facet of the semiconductor optical amplifier and the optical output is arranged onto an output facet of the semiconductor optical amplifier, opposing the input facet, and the optical input is non-parallel with a normal direction of the input facet and/or the optical output is non-parallel with a normal direction of the output facet.

In another implementation form of the first aspect, the active region is configured to amplify a plurality of optical lines of different wavelengths in the optical signal propagating in the waveguide.

According to a second aspect, a semiconductor optical amplifier array comprises a plurality of semiconductor optical amplifiers according first aspect, wherein the plurality of semiconductor layers is common for each semiconductor optical amplifier in the semiconductor optical amplifier array.

According to a second aspect, a method for forming at least one waveguide comprises: providing a semiconductor stack comprising a plurality of semiconductor layers epitaxially deposited on a substrate; forming a stop layer onto the semiconductor stack; forming an aluminum-rich layer onto the stop layer; and forming at least one waveguide by etching the aluminum-rich layer, wherein the at least one waveguide comprises at least two bent sections; wherein the plurality of semiconductor layers comprises an active region configured to amplify an optical signal propagating in the at least one waveguide.

Many of the attendant features will be more readily appreciated as they become better understood by reference to the following detailed description considered in connection with the accompanying drawings.

### DESCRIPTION OF THE DRAWINGS

In the following, example embodiments are described in more detail with reference to the attached figures and drawings, in which:

FIG. 1 illustrates a schematic representation of a semiconductor optical amplifier according to an embodiment;

FIG. 2 illustrates a schematic representation of a semiconductor optical amplifier according to another embodiment;

FIG. 3 illustrates a schematic representation of a waveguide according to an embodiment;

FIG. 4 illustrates a schematic representation of a waveguide according to another embodiment;

FIG. 5 illustrates a schematic representation of a waveguide according to another embodiment;

FIG. 6 illustrates a schematic representation of waveguides according to an embodiment;

FIG. 7 illustrates a schematic representation of a semiconductor optical amplifier according to another embodiment;

FIG. 8 illustrates a schematic flow chart representation of a method for forming at least one waveguide according to an embodiment; and

FIG. 9 illustrates far-field images according to an embodiment.

In the following, identical reference signs refer to similar or at least functionally equivalent features.

### DETAILED DESCRIPTION

In the following description, reference is made to the accompanying drawings, which form part of the disclosure, and in which are shown, by way of illustration, specific aspects in which the present disclosure may be placed. It is understood that other aspects may be utilized, and structural or logical changes may be made without departing from the scope of the present disclosure. The following detailed description, therefore, is not to be taken in a limiting sense, as the scope of the present disclosure is defined by the appended claims.

For instance, it is understood that a disclosure in connection with a described method may also hold true for a corresponding device or system configured to perform the method and vice versa. For example, if a specific method step is described, a corresponding device may include a unit to perform the described method step, even if such unit is not explicitly described or illustrated in the figures. On the other hand, for example, if a specific apparatus is described based on functional units, a corresponding method may include a step performing the described functionality, even if such step is not explicitly described or illustrated in the figures. Further, it is understood that the features of the various example aspects described herein may be combined with each other, unless specifically noted otherwise.

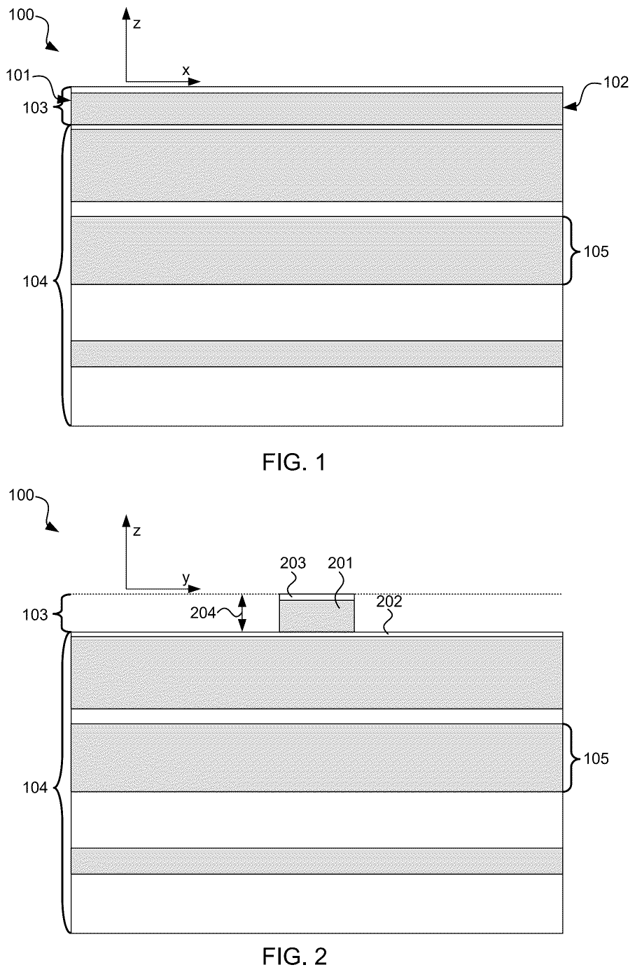

FIG. 1 illustrates a schematic representation of a semiconductor optical amplifier according to an embodiment.

According to an embodiment, a semiconductor optical amplifier 100 comprises an optical input 101 and an optical output 102.

The semiconductor optical amplifier 100 may further comprise a waveguide 103 optically coupled to the optical input 101 and to the optical output 102, wherein the waveguide comprises at least two bent sections.

In the embodiment of FIG. 1, a semiconductor optical amplifier (SOA) 100 comprising one waveguide 103 is illustrated. The ends of the waveguide 103 may function as the optical input 101 and as the optical output 102 or at least as parts of the optical input 101 and the optical output 102. In other embodiments, the SOA 100 may comprise other components between the waveguide 103 and the optical input 101 and/or between the waveguide 103 and the optical output 102. The optical input 101 can comprise any component/part of the SOA 100 that can be used to input optical signals into the waveguide 103. The optical output 102 can comprise any component/part of the SOA 100 that can be used to output optical signals from the waveguide 103.

The waveguide 103 may also be referred to as an optical waveguide or similar.

Herein, when two components/parts are optically coupled, optical signals can be transmitted between the components/parts.

Herein, a bent section of the waveguide 103 may refer to a section of the waveguide 103 that has a non-zero bend radius. The bend radius of a bent section may be constant or non-constant. In some embodiments, the waveguide 103 may comprise a plurality of bent sections. Each bent section may have a different bend radius.

The semiconductor optical amplifier 100 may further comprise a plurality of semiconductor layers 104 epitaxially deposited on a substrate, wherein the waveguide 103 is positioned on top of the plurality of semiconductor layers 104 and the plurality of semiconductor layers 104 comprises an active region 105 configured to amplify an optical signal propagating in the waveguide 103.

The active region 105 may also be referred to as an active layer or similar.

The embodiment of FIG. 1 illustrates a simplified example of the plurality of semiconductor layers 104. The plurality of semiconductor layers 104 may comprise various different layers and materials, such as those disclosed herein. The plurality of semiconductor layers 104 may also be referred to as a semiconductor stack or similar.

It should be appreciated that the optical signal propagating in the waveguide 103 may not be confined only to the waveguide 103. Rather, some part of the optical signal may also propagate in the plurality of semiconductor layers 104, such as in the active region 105. Thus, some layers of the plurality of semiconductor layers 104 may also act as a waveguide. Thus, the optical input 101 and the optical output 102 may also comprise parts of the plurality of semiconductor layers 104 in addition to the ends of the waveguide 103.

It should be appreciated that the embodiment of FIG. 1 only illustrates a side view of the SOA 100 in the xz-plane. The waveguide 103 can have various different shapes, such as those disclosed herein, in the xy-plane.

The at least two bent sections of the waveguide 103 can provide spatial mode filtering of optical signals propagating in the waveguide 103. Spatial modes may also be referred to as optical modes. For example, at least two bent sections can filter out higher order optical modes from the optical signal propagating in the waveguide 103.

Filtering out of higher order optical modes can lead to a better beam quality factor of the SOA 100 output, because of spatial modes reduction from the signal. For example, spatial modes of higher orders can leak out of the at least one waveguide in the bent sections.

SOAs with a bent waveguide may provide the same gain as SOAs with a linear tilted waveguide, but a smaller footprint. For example, measurements have shown no difference in the gain for linear and bent waveguides at room temperature with 1280 nanometer (nm) wavelength at different powers: 40 dB gain at −20 dBm input power, 35 dB gain at −10 dBm, 28 dB gain at 0 dBm, 20 dB gain at 10 dBm. However, the width of the chips with bent waveguide may be down to, for example, 80 μm.

FIG. 2 illustrates a schematic representation of a semiconductor optical amplifier according to another embodiment.

The embodiment of FIG. 2 illustrates a cross-sectional view of the SOA 100 in the yz-plane.

According to an embodiment, the waveguide 103 comprises an aluminum (Al)-rich layer 201.

The waveguide 103 may further comprise a cap layer 203. The cap layer 203 may comprise, for example, a p-type aluminum-rich layer that can function as a source of carriers.

The plurality of semiconductor layers 104 may further comprise a stop layer 202.

In the embodiments of FIGS. 1 and 2, the waveguide 103 is illustrated as a separate structure from the plurality of semiconductor layers 104. In other embodiments, the waveguide 103 and/or some parts of the waveguide 103 may be considered to be part of the plurality of semiconductor layers 104.

In the embodiments of FIG. 1 and FIG. 2, the stop layer 202 extends to the edges of the plurality of semiconductor layers 104 along the y-direction. In other embodiments, the stop layer 202 may not extend to the edges of the plurality of semiconductor layers 104 along the y-direction. For example, in some embodiments, the width of the stop layer 202 in the y-direction may be substantially equal to the width of the Al-rich layer 201 and/or substantially equal to the width of the cap layer 203.

According to an embodiment, a width of the waveguide 103 is in the range of 3 to 5 μm.

According to an embodiment, the waveguide 103 comprises a ridge waveguide on top of the plurality of semiconductor layers 104.

Herein, a ridge waveguide may refer to a waveguide that forms a ridge-like shape onto the plurality of semiconductor layers 104. For example, in the embodiments of FIGS. 1 and 2, the waveguide 103 has a ridge-like shape in the yz-plane. The ridge of the ridge waveguide may comprise one or more structures/layers of the waveguide. For example, in the embodiments of FIGS. 1 and 2, the ridge comprises the cap layer 203 and the Al-rich layer 201. In other embodiments, the ridge may further comprise the stop layer 202.

A ridge waveguide may have a rectangular or substantially rectangular cross section. Thus, a rectangular waveguide can have a top surface and side surfaces. For example, in the embodiment of FIG. 2, a rectangular cross section of the waveguide 103 is illustrated.

According to an embodiment, a height of the ridge waveguide is in the range of 1 to 3 μm.

The height 204 of the ridge waveguide may be measured along a direction of the stacking of the layers in the plurality of semiconductor layers 104. For example, in the embodiment of FIG. 2, the plurality of semiconductor layers is stacked in the z-direction and thus the height 204 of the ridge waveguide may be measured in the z-direction. The height 204 of the ridge waveguide may measure how much the ridge waveguide protrudes from the surrounding surface. Thus, in the embodiment of FIG. 2, the height 204 of the ridge waveguide 103 comprises the height of the Al-rich layer 201 and the height of the cap layer 203. In embodiments where the stop layer 202 has a substantially equal width to the Al-rich layer 201 and/or the cap layer 203, the height 204 of the ridge waveguide may further comprise the height of the stop layer 202.

It should be appreciated that the embodiment of FIG. 2 only illustrates a cross-sectional view of the waveguide 103 in the yz-plane. The waveguide 103 can have various different shapes, such as those disclosed herein, in the xy-plane.

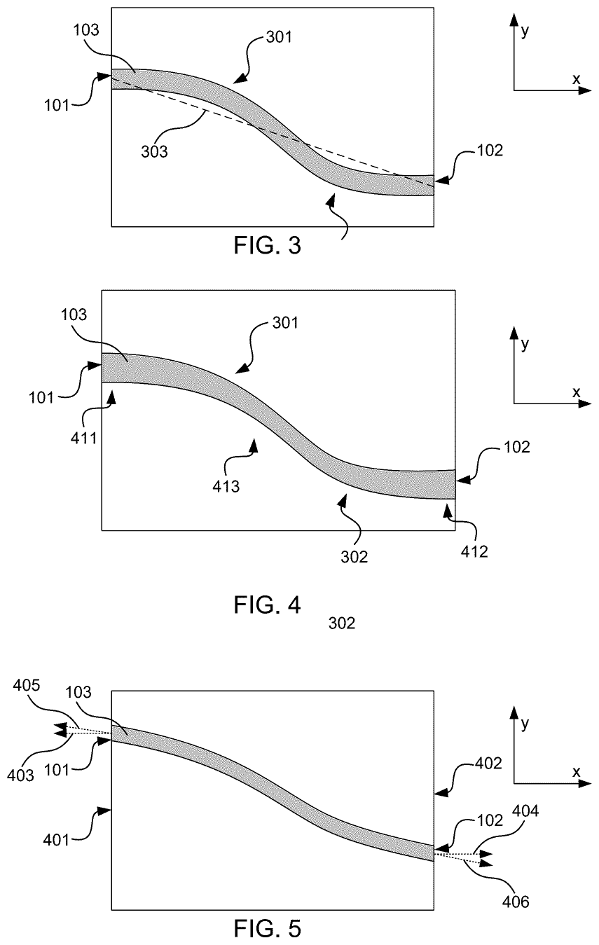

FIG. 3 illustrates a schematic representation of a waveguide according to an embodiment.

The embodiment of FIG. 3 illustrates one example of waveguide 103 comprising at least two bent sections. In other embodiments, the waveguide 103 may comprise any number of bents sections in any configuration.

The waveguide 103 may be bent in a plane orthogonal to the stacking of the layers in the plurality of semiconductor layers 104. Herein, when the waveguide 103 is bent in a plane, the bend radius of the at least two bent sections of the waveguide 103 may be in that plane. For example, in the embodiment of FIG. 3, the plurality of semiconductor layers 104 are stacked along the z-direction and thus, the plane orthogonal to the stacking of the layers in the plurality of semiconductor layers 104 is the xy-plane. As is illustrated in the embodiment of FIG. 3, the waveguide 103 is bent in the xy-plane and thus the bend radius of the at least two bent sections is in the xy-plane.

According to an embodiment, the waveguide 103 comprises at least a first bent section 301 and a second bent section 302, wherein the first bent section 301 is located on a first side of a straight line 303 from the optical input 101 to the optical output 102 and the second bent section 302 is located on a second side of the straight line 303 from the optical input 101 to the optical output 102.

The second side of the straight line 303 from the optical input 101 to the optical output 102 can be different from the first side of the straight line 303 from the optical input 101 to the optical output 102. The second side can oppose the first side.

The embodiment of FIG. 3 illustrates an example of a first bent section 301 located on a first side of a straight line 303 from the optical input 101 to the optical output 102 and a second bent section 302 located on a second side of the straight line 303 from the optical input 101 to the optical output 102.

Herein, the first bent section 301 is located on the first side of a straight line 303 when at least some part of the waveguide 103 along the first bent section 301 is located on the first side of a straight line 303. Similarly, the second bent section 302 is located on the second side of a straight line 303 when at least some part of the waveguide 103 along the second bent section 302 is located on the second side of a straight line 303.

For example, the waveguide 103 can have an S-like shape. Herein, an S-like shaped waveguide may refer to a waveguide comprising a first bent section 301 and a second bent section 302, wherein the first bent section 301 is located on a first side of a straight line from the optical input 101 to the optical output 102, the second bent section 302 is located on a second side of the straight line, and the first bent section and the second bent section have substantially equal bend radii.

Since the waveguide 103 comprises the at least two bent sections, the length of the waveguide 103 may be greater than the displacement of the optical input 101 to the optical output 102 in the xy-plane.

According to an embodiment, the length of the waveguide 103 is at least 100 μm greater than the displacement of the optical input 101 to the optical output 102 in the xy-plane.

According to an embodiment, a length of the waveguide 103 is in the range of 4.3 to 12.3 mm.

According to an embodiment, the first bent section 301 has a first bend radius and the second bent section 302 has a second bend radius, different from the first bend radius.

In other embodiments, the first bent section 301 and the second bent section 302 may have equal or substantially equal bend radii.

According to an embodiment, a bend radius of the at least two bent sections is in the range of 7 to 16 mm.

With the at least two bent sections in the waveguide 103, dimensions of the SOA 100 and/or of a SOA array along the y-direction can be reduced. Thus, the footprint of the SOA 100 can be reduced.

FIG. 4 illustrates a schematic representation of a waveguide according to another embodiment.

According to an embodiment, the waveguide 103 comprises at least one flared section 411, 412. For example, the waveguide 103 may comprise a central section 413 having a first width. The waveguide 103 may further comprise a first flared section 411 having a second width greater than the first width. The first flared section 411 may be coupled to the optical input 101. The waveguide 103 may further comprise a second flared section 412 having a third width greater than the first width. The second flared section 412 may be coupled to the optical output 102. In some embodiments, the central section 413 may have a first height, the first flared section 411 may have a second height greater than the first height, and/or the second flared section 412 may have a third height greater than the first height. Alternatively or additionally, the central section 413 of the waveguide may be referred to as a tapered section.

The width of the at least one flared section 411 may, for example, vary in the range 10 to 100 μm.

With the at least one flared section 411, 412 a greater amplification may be achieved. Chip length may be reduced while keeping the amplification on the same level with a non-flared longer chip. The at least one flared section 411, 412 may also improve the noise figure.

In some embodiments, the first/second flared section may be part of a bent section.

FIG. 5 illustrates a schematic representation of a waveguide according to another embodiment.

According to an embodiment, the optical input 101 is arranged onto an input facet 401 of the semiconductor optical amplifier 100 and the optical output 102 is arranged onto an output facet 402 of the semiconductor optical amplifier 100, opposing the input facet 401, and the optical input 101 is non-parallel with a normal direction 403 of the input facet 401 and/or the optical output 102 is non-parallel with a normal direction 404 of the output facet 402.

The input facet 401 may also be referred to as a first optical facet and the output facet 402 may also be referred to as a second optical facet.

Herein, a facet may refer to a transmitting or receiving area on a surface for transmitting or receiving light, respectively.

According to an embodiment, a length of the SOA 100 along a direction from the input facet 401 to the output facet 402 is in the range 4-12 mm, in the range 5-11 mm, in the range 6-10 mm, or in the range 7-9 mm. For example, in the embodiment of FIG. 5, the length of the SOA 100 may be measured along the x-direction.

According to an embodiment, a width of the SOA 100 in a direction orthogonal with a direction from the input facet 401 to the output facet 402 is in the range 80 to 400 μm. For example, in the embodiment of FIG. 5, the width of the SOA 100 may be measured along the y-direction.

In the embodiment of FIG. 5, arrow 405 indicates the direction of the optical input 101, which is non-parallel with the normal direction 403 of the input facet 401. Similarly, arrow 406 indicates the direction of the optical output 102, which is non-parallel with the normal direction 404 of the output facet 402.

The direction of the optical input 101 and/or the direction of the optical output 102 may refer to the direction of the waveguide 103 at the input facet 401 and at the output facet 402, respectively.

According to an embodiment, an angle between the direction of the optical input 101 and the normal direction 403 of the input facet 401 is in the range of 3 to 5 degrees.

According to an embodiment, an angle between the direction of the optical output 102 and the normal direction 404 of the output facet 402 is in the range of 3 to 5 degrees.

The angle between the direction of the optical input 101 and the normal direction 403 of the input facet 401 and/or the angle between the direction of the optical output 102 and the normal direction 404 of the output facet 402 may be measured in a plane orthogonal to the stacking of the layers in the plurality of semiconductor layers 104. For example, in the embodiment of FIG. 5, the plurality of semiconductor layers is stacked along the z-direction and thus, the plane orthogonal to the stacking of the layers in the plurality of semiconductor layers 104 is the xy-plane.

By having the optical input 101 non-parallel with the normal direction 403 of the input facet 401, reflections in the optical input 101 can be reduced. Similarly, by having the optical output 102 non-parallel with the normal direction 404 of the output facet 402 reflections in the optical output 102 can be reduced.

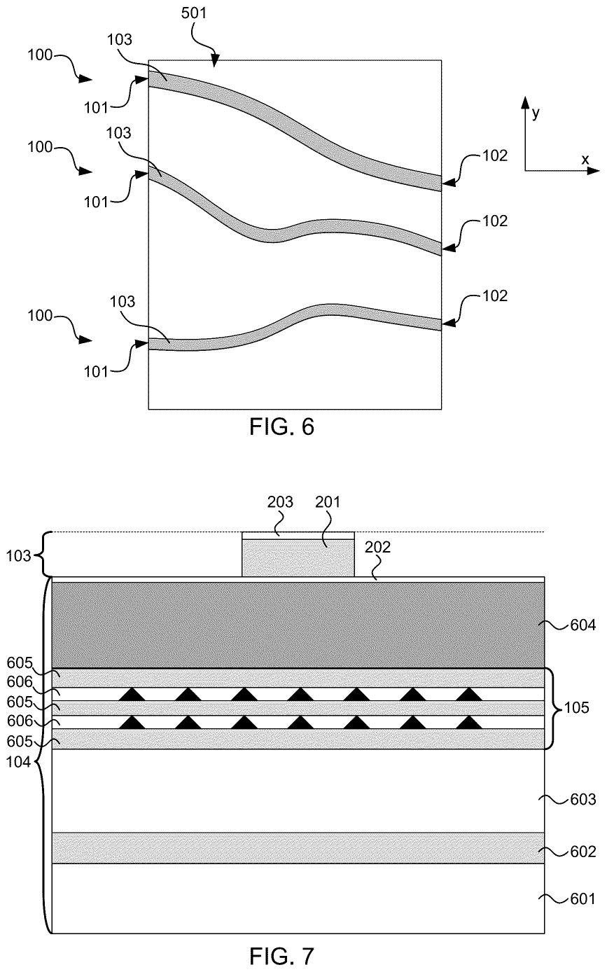

FIG. 6 illustrates a schematic representation of waveguides according to another embodiment.

According to an embodiment, a semiconductor optical amplifier array 501 comprises a plurality of semiconductor optical amplifiers, wherein the plurality of semiconductor layers is common for each semiconductor optical amplifier in the semiconductor optical amplifier array.

In the embodiment of FIG. 6, an SOA array 501 comprises three SOAs.

The semiconductor optical amplifier array 501 may comprise any number of waveguides, such as 2-32 waveguides.

Each SOA in the SOA array 501 may be configured to guide and amplify an independent optical signal from the corresponding optical input 101 to the corresponding optical output 102.

With the at least two bent sections in the plurality of waveguides, the waveguides of different SOAs in a SOA array 501 can be placed closer to each other. Thus, the footprint of the SOA array 501 can be reduced.

As illustrated in the embodiment of FIG. 6, the waveguide of each SOA 100 in the SOA array 501 can have a different shape. In other embodiments, at least some waveguides can have the same shape.

In some embodiments, a distance between each corresponding optical input and optical output pair can be constant while the waveguides of different SOAs 100 can be of different lengths.

In some embodiments, the SOA array 501 may also be referred to as a monolithic SOA array. In a monolithic SOA array, the same plurality of semiconductor layers 104 can be utilized for amplifying optical signals in each SOA 100 of the SOA array 501.

According to an embodiment, the waveguide of each SOA 100 in the SOA array 501 comprises a first bent section 301 and a second bent section 302. The first bent section 301 of each waveguide can be located on a first side of a straight line from an optical input coupled to the waveguide to the optical output 102 coupled to the waveguide. The second bent section 302 of each waveguide can be located on a second side of the straight line 303 from the optical input 101 coupled to the waveguide to the optical output 102 coupled to the waveguide.

Any disclosure herein in relation to the SOA 100 may apply to any of or all of the SOAs 100 in the SOA array 501.

FIG. 7 illustrates a schematic representation of a semiconductor optical amplifier according to another embodiment.

According to an embodiment, the active region 105 is configured to amplify a plurality of optical lines of different wavelengths in the optical signal propagating in the waveguide 103.

Herein, a SOA capable of amplifying a plurality of optical lines of different wavelengths in the optical signal may be referred to as a comb-SOA. For example, an optical signal, such as a wavelength-division multiplexing (WDM) signal, comprising an optical frequency comb can be fed into the waveguide of the comb-SOA and the comb-SOA may amplify each optical line comprised in the frequency comb. In the optical frequency comb, the distance between two consecutive optical lines can be constant.

According to an embodiment, a refractive index of the active region 105 is greater than a refractive index of the stop layer 202 and/or the refractive index of the active region 105 is greater than a refractive index of the cap layer 203.

According to an embodiment, the active region comprises at least one of: quantum wells (QWs), quantum dots (QDs), quantum wires, or/and quantum dashes.

QDs can be better than QWs in terms of noise figures as they may reach a higher population inversion and, therefore, so amplified spontaneous emission may be less.

According to an embodiment, the plurality of semiconductor layers is realized in a III-V semiconductor material composition.

A SOA 104 realized in a III-V semiconductor material composition comprising an active region of quantum dots, quantum wells, and/or quantum dashes may be used to implement a comb-SOA. For example, the quantum dots of the active region may have a plurality of different sizes. Quantum dots of different sizes may be distributed by the sizes thereof in different quantum dot layers. The size of a quantum dot may affect the wavelength at which stimulated emission of light takes place at said quantum dot. Thereby, amplification of light in the active region comprising quantum dots of different sizes may take place at a plurality of peak wavelengths.

The III-V semiconductor material composition can comprise, for example, a gallium arsenide (GaAs) based material platform. The quantum dots, quantum wells, and/or quantum dashes can be used for optical signal amplification.

For example, the active region 105 may comprise InGaAs QWs or indium arsenide (InAs) quantum dots (QDs).

Herein, when the plurality of semiconductor layers is realized in gallium arsenide and/or in a GaAs based material platform, GaAs may be used as the main material of the plurality of semiconductor layers 104. For example, GaAs can be used as the substrate or some other material, such as other III-V semiconductor materials, can be used as the substrate, GaAs can be grown onto the substrate, for example epitaxially, and other structures can be grown onto the GaAs. Such a semiconductor structure may comprise, for example, a semiconductor heterostructure comprising other materials grown on the GaAs. The other materials can comprise, for example, aluminum arsenide (AlAs), indium gallium arsenide (InGaAs), aluminum gallium arsenide (AlGaAs) and/or InAs.

According to an embodiment, the plurality of semiconductor layers 104 further comprises a bottom cladding layer 603 and a top cladding layer 604, wherein a refractive index of the active region 105 is greater than a refractive index of the bottom cladding layer 603 and a refractive index of the top cladding layer 604.

According to an embodiment, an effective refractive index of a fundamental mode of the at least one waveguide at a central wavelength of 1280 nanometers is in the range of 3.3 to 3.4. The effective refractive index may vary depending on, for example, the ridge height of the at least one waveguide.

The active region 105 may be located between the bottom cladding layer 603 and the top cladding layer 604.

By having the refractive index of the active region 105 being greater than the refractive index of the bottom cladding layer 603 and the refractive index of the top cladding layer 604, the optical signal can be efficiently confined into the active region 105.

For example, in the embodiment of FIG. 7, the plurality of semiconductor layers 104 comprises a substrate layer 601, such as a GaAs substrate layer, an n-type cap layer 602, such as a layer of n-type GaAs, a bottom cladding layer 603, such as a layer of n-type AlGaAs, the active region 105, and a top cladding layer 604, such as a layer of p-type AlGaAs.

According to an embodiment, the plurality of semiconductor layers 104 are realized in gallium arsenide and the active region 105 comprises indium arsenide quantum dots.

According to an embodiment, the active region 105 comprises indium arsenide quantum dots embedded in indium gallium arsenide quantum wells.

Herein, a sublayer of InGaAs quantum well may refer to an InGaAs layer of the active region 105 that is so thin that the layer forms a QW. The active region 105 may comprise any number of the InGaAs sublayers.

The InAs QDs embedded in InGaAs QWs may also be referred to as (In, Ga) As QDs.

The InAs QDs embedded in the InGaAs QWs may be, for example, epitaxially grown.

For example, in the embodiment of FIG. 7, the active region 105 may comprise alternating buffer layers 605 and InGaAs QW layers 606 with InAs QDs embedded into the InGaAs QW layers 606. The alternating layers may be repeated any number of times.

According to an embodiment, the active region is configured to amplify a plurality of optical lines of different wavelengths in the optical signal propagating in the waveguide.

The embodiment of FIG. 7 illustrates only one example of a QD heterostructure realized in GaAs material platform. In other embodiments, the plurality of semiconductor layers 104 may differ from what is depicted in the embodiment.

QD comb-SOAs can enable power savings in multi terabit per second datacom links. Such SOAs can be used as amplifiers for several wavelength channels.

QD SOAs can provide improved noise figures compared to, for example, SOAs based on InP QW structures.

In the embodiment of FIG. 7, the SOA 100 may comprise, for example, p-type AlGaAs as the Al-rich layer 201, InGaP as the stop layer 202, and p-type GaAs as the cap layer 203.

The SOA 100 may provide a high-power conversion efficiency (PCE). For example, the PCE of the SOA 100 may be up to 25% at a 350 milliwatt of output power and at a temperature of 85° C.

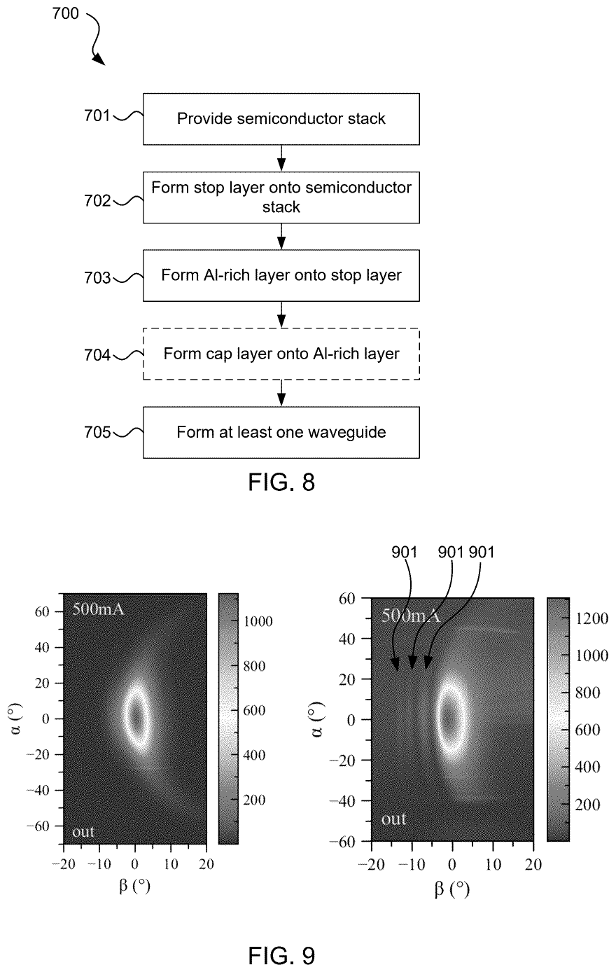

FIG. 8 illustrates a schematic flow chart representation of a method for forming at least one waveguide according to an embodiment.

According to an embodiment, a method 700 for forming at least one waveguide comprises providing 701 a semiconductor stack comprising a plurality of semiconductor layers epitaxially deposited on a substrate.

The method 700 may further comprise forming 702 a stop layer onto the semiconductor stack.

The stop layer may be formed by, for example, depositing an appropriate material onto the semiconductor stack.

The stop layer may also be referred to as an etch stop layer or similar.

The method 700 may further comprise forming 703 an Al-rich layer onto the stop layer.

The Al-rich layer may be formed by, for example, depositing an appropriate material onto the stop layer.

In some embodiments, the method 700 may further comprise forming a cap layer 704 onto the Al-rich layer. In other embodiments, the cap layer may not be formed.

The cap layer may be formed by, for example, depositing an appropriate material onto the Al-rich layer.

The method 700 may further comprise forming 705 at least one waveguide by etching the Al-rich layer, and the cap layer if the cap layer has been formed, wherein the at least one waveguide comprises at least two bent sections.

The etching of the Al-rich layer and the cap layer may comprise, for example, forming a mask corresponding to the shape of the at least one waveguide onto the cap layer, etching areas of the Al-rich layer and of the cap layer not covered by the mask, and removing the mask. The forming of the mask, etching areas of the Al-rich layer and of the cap layer not covered by the mask, and removing the mask may be performed in various ways depending on, for example, the materials used and the method used for the etching.

The stop layer can be utilized when forming the at least one waveguide. When etching the Al-rich layer and of the cap layer, the stop layer can prevent etching of the plurality of semiconductor layer 104.

The plurality of semiconductor layers may comprise an active region configured to amplify an optical signal propagating in the at least one waveguide.

Any disclosure herein in relation to the semiconductor optical amplifier 100 may also apply to the method 700.

FIG. 9 illustrates far-field images according to an embodiment.

Left far-field image in FIG. 9 corresponds to an 8 mm chip with a tilted waveguide at 25° C. with a 500-milliamp control current.

Right far-field image in FIG. 9 corresponds to an 8 mm chip with S-like shaped waveguide at 25° C., 500-milliamp control current.

The mode leakage of the higher order spatial modes is distinguishable in the far-field images as interference pattern 901 on the side of the main beam. Thus, the higher order spatial modes can be effectively filtered out when, for example, the semiconductor optical amplifier is coupled to a receiver.

The bent sections may not worsen the noise figure of the semiconductor optical amplifier compared to a tilted waveguide design. Thus, improved beam quality and smaller footprint can be achieved at a similar gain and noise figure level.

For example, a noise figure can be defined as

$$10 \cdot {log}_{10} ( \frac{2 {P}_{ASE}^{Δ}}{{GC}_{in} hv Δ f} ) ,$$

where G is the SOA gain by waveguide, Cᵢₙ is input coupling efficiency,

$${P}_{A S E}^{Δ}$$

is amplified spontaneous emission optical power within optical bandwidth Δf, h is the Planck constant, and v is the photon frequency.

The experiments conducted demonstrated similar results for tilted and bent waveguide designs: noise figure in the range of 4.2-4.4 dB for a wavelength range of 1270-1280 nm and input power from −25 dBm to 0 dBm.

Any range or device value given herein may be extended or altered without losing the effect sought. Also, any embodiment may be combined with another embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

Aspects of any of the embodiments described above may be combined with aspects of any of the other embodiments described to form further embodiments without losing the effect sought.

The term ‘comprising’ is used herein to mean including the method, blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

1. A semiconductor optical amplifier comprising:
an optical input;
an optical output;
a waveguide optically coupled to the optical input and to the optical output, wherein the waveguide comprises at least two bent sections; and
a plurality of semiconductor layers epitaxially deposited on a substrate, wherein the waveguide is positioned on top of the plurality of semiconductor layers and the plurality of semiconductor layers comprises an active region configured to amplify an optical signal propagating in the waveguide;
wherein the plurality of semiconductor layers further comprises a bottom cladding layer and a top cladding layer, wherein a refractive index of the active region is greater than a refractive index of the bottom cladding layer and a refractive index of the top cladding layer.

2. The semiconductor optical amplifier according to claim 1, wherein the active region comprises at least one of:
quantum wells, quantum dots, quantum wires, or/and quantum dashes.

3. The semiconductor optical amplifier according to claim 1, wherein the plurality of semiconductor layers is realized in a III-V semiconductor material composition.

4. The semiconductor optical amplifier according to claim 1, wherein the plurality of semiconductor layers is realized in gallium arsenide and the active region comprises indium arsenide quantum dots.

5. The semiconductor optical amplifier according to claim 1, wherein the active region comprises indium arsenide quantum dots embedded in indium gallium arsenide quantum wells.

6. The semiconductor optical amplifier according to claim 1, wherein the waveguide comprises a ridge waveguide on top of the plurality of semiconductor layers.

7. The semiconductor optical amplifier according to claim 6, wherein a height of the ridge waveguide is in a range of 1 to 3 micrometers.

8. The semiconductor optical amplifier according to claim 1, wherein a bend radius of the at least two bent sections is in a range of 7 to 16 millimeters.

9. The semiconductor optical amplifier according to claim 1, wherein the waveguide comprises at least a first bent section and a second bent section, wherein the first bent section is located on a first side of a straight line from the optical input to the optical output and the second bent section is located on a second side of the straight line from the optical input to the optical output.

10. The semiconductor optical amplifier according to claim 9, wherein the first bent section has a first bend radius and the second bent section has a second bend radius, different from the first bend radius.

11. The semiconductor optical amplifier according to claim 1, wherein the optical input is arranged onto an input facet of the semiconductor optical amplifier and the optical output is arranged onto an output facet of the semiconductor optical amplifier, opposing the input facet, and the optical input is non-parallel with a normal direction of the input facet and/or the optical output is non-parallel with a normal direction of the output facet.

12. The semiconductor optical amplifier according to claim 1, wherein the waveguide comprises at least one flared section.

13. The semiconductor optical amplifier according to claim 12, wherein the waveguide comprises a central section having a first width, a first flared section having a second width, greater than the first width, and a second flared section having a third width, greater than the first width.

14. The semiconductor optical amplifier according to claim 1, wherein the active region is configured to amplify a plurality of optical lines of different wavelengths in the optical signal propagating in at least one waveguide.

15. A semiconductor optical amplifier array comprising a plurality of semiconductor optical amplifiers according to claim 1, wherein the plurality of semiconductor layers is common for each semiconductor optical amplifier in the semiconductor optical amplifier array.

16. A method for forming at least one waveguide, the method comprising:
providing a semiconductor stack comprising a plurality of semiconductor layers epitaxially deposited on a substrate;
forming a stop layer onto the semiconductor stack;
forming an aluminum-rich layer onto the stop layer;
forming at least one waveguide by etching the aluminum-rich layer, wherein the at least one waveguide comprises at least two bent sections;
wherein the plurality of semiconductor layers comprises an active region configured to amplify an optical signal propagating in the at least one waveguide.
